(19) United States
(12) Patent Application Publication
(10) Pub. No.: US 2022/0093774 A1
(43) Pub. Date: Mar. 24, 2022

(54) HETEROJUNCTION BIPOLAR TRANSISTOR AND METHOD OF MAKING THE SAME

(71) Applicant: SiEn (QingDao) Integrated Circuits Co., Ltd., Qingdao (CN)

(72) Inventors: Min-Hwa CHI, Qingdao (CN); Richard Ru-Gin CHANG, Qingdao (CN)

(73) Assignee: SiEn (QingDao) Integrated Circuits Co., Ltd., Qingdao (CN)

(21) Appl. No.: 17/461,803

(22) Filed: Aug. 30, 2021

(30) Foreign Application Priority Data
Sep. 21, 2020 (CN) 202010993656.3

(51) Int. Cl. H01L 29/737; H01L 29/165; H01L 29/78; H01L 29/66

(52) U.S. Cl. CPC H01L 29/737; H01L 29/66545; H01L 29/785; H01L 29/165

(57) ABSTRACT

The present invention provides a heterojunction bipolar transistor and a method of making the same, applying fin replacement technology, fins are formed on a substrate, a well region served as a collector region is formed in the substrate, and a bottom of the fins connects to the well region served as the collector. A first part of the well region corresponding to the fin is removed, i.e. hollow a part of the fins out to form a first opening, and material of a base region is then deposited to form a fin base. A remaining part of the fin corresponding to the well region is removed, i.e. hollow the remaining part of the fins out to form a second opening, and the base region is then deposited. Then, on the base region, an emitter region is formed. A base region epitaxy cap layer and an emitter region epitaxy cap layer are formed outside the fin base and the emitter region respectively. Above-mentioned method may be integrated to the FinFET technology platform. As such, in the present invention, equivalent base and resistances of the collector electrode of the heterojunction bipolar transistor are less, leakage current of the transistor is low, electrical performance is great, and integration with a FinFET device is easier to promote integration density of the device.

### FIELD OF THE INVENTION

The present invention relates to semiconductor device technical field, and especially, relates to a heterojunction bipolar transistor (HBT) and a method of making the same.

### BACKGROUND OF THE INVENTION

Notable features of traditional vertical bipolar transistor (VBT) technology, the main technology includes e: 1) polysilicon emitter, shrinking a base width to under 100 nm; 2) self-aligned emitter-base, and deep and shallow trench isolation to reduce device size as well as a stray capacitor; 3) self-aligned intrinsic collector region with heavy doping to reduce collector resistance for high speed. Nowadays, IC's with heterojunction bipolar transistors (HBT) based on CMOS technology have been widely used in applications for vehicle radars, high-speed wireless, optical data links, and high-accuracy analog circuits. HBT is similar to conventional VBT in structure, but the difference therebetween is in replacing a base by SiGe with a small amount of C doping. Advanced CMOS technology integrated with SiGe HBT technology (widely referred to as BICMOS) may lead to future 5G communication standards with high frequency band up to 40 GHz, and therefore they are strong technology competitors for high data rate wireless or fiber backhaul applications.

The deeper P-N junction in Fin structure may be improved in leakage and defects. An optimized fin field effect transistor (i.e. FinFET) shows an almost ideal low leakage current and great temperature stability up to 125° C. The improved P-N junction leakage current in FinFET transistor at a high temperature may be owing to reduced defects in the junction. A vertical pnp bipolar transistor with an optimized fin junction presents great performance (β and linearity), low leakage current, high open-base breakdown voltage (BVCEO) and nearly perfect ideality factor n≈1.01, also no leakage current related to stacking faults induced by a high stress in SiGe p+/n junction.

The SiGe BiCMOS technology with (npn) HBT, is success because of its higher integration capability for mass production with excellent performance (through narrower band-gap of SiGe) competitive cost as essential to the communication market. Until now, the most advanced SiGe HBT may be integrated with 40 nm CMOS platform. However, the SiGe HBT is not available so far on the platform of 14 nm or beyond technology nodes probably due to the process complexity of FinFET. Since 5G communication is already a real life, we need a high-performance CMOS with SiGe HBT device and integration method on the advanced FinFET platform.

### SUMMARY OF THE INVENTION

In view of above-mentioned drawbacks of the current technology, an object of the present invention is to provide a heterojunction bipolar transistor (HBT) technology integrated on FinFET platform and a method of making the same. The method applies replacement technology to form a heterojunction bipolar transistor (HBT) on the FinFET platform. Taking the formation of an npn transistor as an example, the (P-type) SiGe doped with C (briefly denoted as SiGe:C) is deposited in a fin as a base region by using the fin replacement technology; the bottom of the fin is connected with an N well served as a collector region; and the polysilicon is formed on top of the fin to serve as an emitter region As such, in the present invention, the equivalent base and collector resistance of the HBT may be less (than those in a traditional HBT), and the integration on the FinFET platform may be more easily.

To implement above-mentioned object and other related objects, the present invention provides a method of making a heterojunction bipolar transistor, comprising: providing a substrate, a plurality of fins in long strip shape and parallel to each other on the substrate, an isolation structure being formed between the adjacent fins, the isolation structure being flush with the fins, the fins comprising a first fin region, and the first fin region comprising a plurality of the fins; doping the substrate, a well region of a second conductivity type being formed in the substrate to form a collector region, the well region corresponding to the first fin region; removing a first part of the fins in the first fin region to form a first opening; forming a first semiconductor material layer having a first conductivity type in the first opening to form a fin base, the second conductivity type being opposite to the first conductivity type; removing a second part of the fins of the first fin region to form a second opening; forming the first semiconductor material layer in the second opening, forming the fin base in the first opening and forming the first semiconductor material layer in the second opening to form a base region, the fin base in the second opening in connected with a fin base in the first opening, the thickness of the first semiconductor layer being smaller than the height of the second opening; and forming a second semiconductor layer having the second conductivity type on the base region to form an emitter region.

Optionally, the step of forming a first semiconductor material layer having a first conductivity type in the first opening to form a fin base further comprises steps of: cleaning a bottom and a sidewall of the first opening; and selective epitaxial growth of P-type SiGe in the first opening.

Optionally, the steps of forming the base region and the emitter region further comprise steps of: cleaning a bottom and a sidewall of the second opening; selective epitaxial growth of P-type SiGe in the second opening; and forming an N-type polysilicon on the P-type SiGe.

Optionally, the P-type SiGe is Boron and C doped SiGe with C in 1-5% of atoms.

Optionally, the N-type polysilicon is As doped polysilicon. Structure to expose at least a part of the fin base and a part of the emitter region; forming a base region epitaxy cap layer outside the fin base, the epitaxy cap layer being connecting to the fin base; and forming an emitter region epitaxy cap layer outside the emitter region, the emitter region epitaxy cap layer being connecting to the emitter region.

Optionally, the base region epitaxy cap layer is P-type SiGe, and the emitter region epitaxy cap layer is n-type polysilicon.

Optionally, the making method further comprises: forming a base region electrode on the base region epitaxy cap layer; forming an emitter electrode on the emitter region epitaxy cap layer; and forming a collector electrode connecting to the well region of collector on the substrate.

Optionally, the making method may further comprise a second fin region, and the making method further comprises steps of: forming a replacement gate stack in a channel region of the fins of the second fin region; forming a source region and a drain region at two ends of the channel region; removing the replacement gate stack to a gate opening exposing the channel region; and forming a gate structure in the gate opening.

Optionally, the second opening is partially formed in the fin base.

Another object of the present invention provides a heterojunction bipolar transistor, comprising: a substrate, on which is formed with a plurality of fins being in long strip shape and parallel to each other, the fins comprising a first fin region, the first fin region comprising a plurality of the fins; a collector region, formed in the substrate, the collector region corresponding to the first fin region; a fin base, formed in the first fin region; a base region formed in the first fin region, the base region and the fin base forming a continuous structure; and an emitter region, formed on the base region.

Optionally, a material of the fin base and the base region is P-type SiGe.

Optionally, a material of the fin base and the base region is C doped SiGe.

Optionally, material of the emitter region is N-type polysilicon.

Optionally, a material of the emitter region is As doped polysilicon.

Optionally, the heterojunction bipolar transistor further comprises: a base region epitaxy cap layer, formed outside the fin base, the base region epitaxy cap layer being connecting to the fin base; and an emitter region epitaxy cap layer, formed outside the emitter region, the emitter region epitaxy cap layer being connecting to the emitter region.

Optionally, the heterojunction bipolar transistor further comprises: a base region electrode, formed on the base region epitaxy cap layer; an emitter electrode, formed on the emitter region epitaxy cap layer; and a collector electrode connecting to the well region of collector on the substrate.

Optionally, the fins further comprise a second fin region, the second fin region is formed with a MOS device, and the MOS device comprises: a source region, a drain region and a channel region, the source region and the drain region being formed at two ends of the fins of the second fin region, and the channel region being positioned between the source region and the drain region; and a gate structure, formed at edge of the channel region.

As mentioned above, benefits of the heterojunction bipolar transistor and the method of making the same according to the present invention are: when making the heterojunction bipolar transistor of the present invention with applying the fin replacement technology, the fin structure may be formed on the substrate and the well region served as the collector region may be formed in the substrate, the bottom of the fin may connect to the well region served as the collector, the material of the base region may be deposited in the fins for the fin base to form the fin base, the material of the base region may be deposited in the fins for forming a heterojunction to form the base region, the fin base is connected with the base region through the epitaxy cap layer, and then various materials are deposited on the base region to be served as the emitter region. Taking an npn heterojunction transistor for example, the well region in the substrate may be N-type doped well region, and the material of the base region may be C doped P-type SiGe (i.e. doped with Boron and Carbon), the material of the emitter region may be As doped N-type polysilicon Si. The electrode contacts of the emitter, base and collector may be positioned on the surface of the device. Above-mentioned method has simple process, and may be integrated on the FinFET technology platform. The technology disclosed here is based on FinFET technology and the most advanced SiGe heterojunction bipolar transistor and provides novel and improved process for integrating SiGe HBT on the advanced FinFET platform at 14 nm or beyond nodes.

As such, for the heterojunction bipolar transistor made with above-mentioned method, its equivalent base and collector resistances are reduced, leakage current of the transistor is low, electrical performance is great, and integration with a FinFET technology is easier for higher integration level.

### BRIEF DESCRIPTION OF THE DRAWINGS

FIG. 1 shows a flow chart of a method of making a heterojunction bipolar transistor according to a first embodiment of the present invention.

FIG. 2 shows a perspective view of fins formed on a substrate.

FIG. 3 shows a perspective view of a well region formed in the structure shown in FIG. 2.

FIG. 4 shows a perspective view of a first mask formed on the structure shown in FIG. 3.

FIG. 5 shows a perspective view of a first opening of the first mask, shown in FIG. 4, formed in the fins of a first fin region.

FIG. 6 shows a perspective view of a fin base formed at the first opening.

FIG. 7 shows a perspective view of a second mask formed on the structure shown in FIG. 6.

FIG. 8 shows a top view of the XY plane shown in FIG. 7 for comparison of the first and second masks.

FIG. 9 shows a perspective view of a second opening of the second mask, shown in FIG. 7, formed in the fins of the first fin region.

FIG. 10 shows a perspective view of a base region formed in the second opening.

FIG. 11 shows a perspective view of an emitter region formed on the base region shown in FIG. 10.

FIG. 12 shows a cross-sectional view of the XZ plane shown in FIG. 11 for illustrating an epitaxy cap layer formed outside the fin base and the emitter region.

### DESCRIPTION OF EMBODIMENTS OF THE INVENTION

Reference is now made to the following concrete examples taken in conjunction with the accompanying drawings to illustrate implementation of the present invention. Persons of ordinary skill in the art having the benefit of the present disclosure will understand other advantages and effects of the present invention. The present invention may be implemented with other examples. For various view or application, details in the present disclosure may be used for variation or change for implementing embodiments within the scope of the present invention.

Please note that the drawings provided here are only for examples but not limited to the specific number or scale shown therein. When implementing the examples according to the drawings, condition, number and proportion of each element may be changed and arrangement of the elements may be in a more complex way.

### First Embodiment

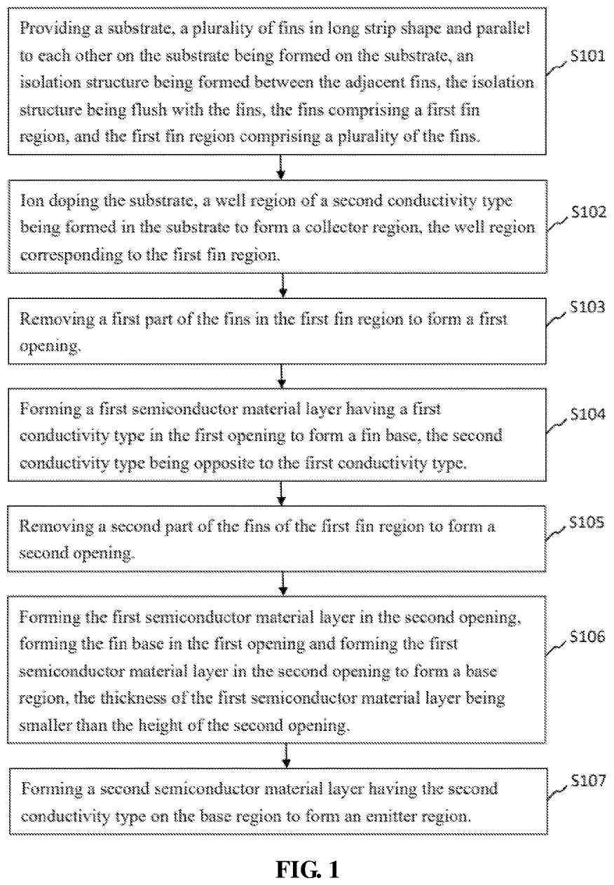

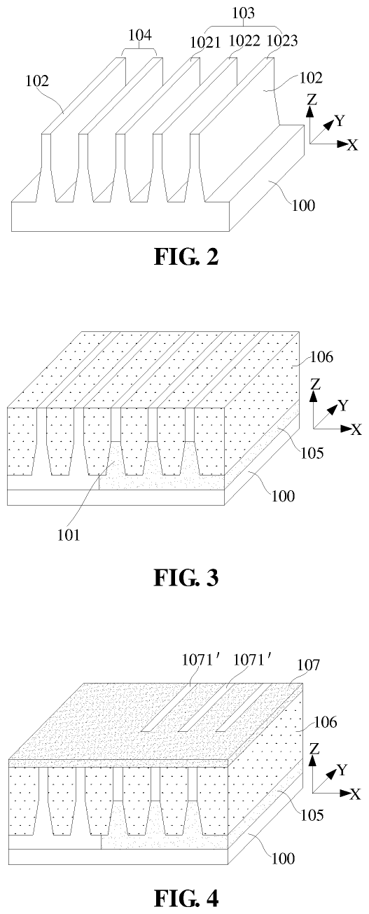

The present embodiment provides a method of making a heterojunction bipolar transistor. As shown in FIG. 1, the method may comprise steps of: step S101: providing a substrate, a plurality of fins in long strip shape and parallel to each other on the substrate being formed on the substrate, an isolation structure being formed between the adjacent fins, the isolation structure being flush with the fins, the fins comprising a first fin region, and the first fin region comprising a plurality of the fins. The substrate of the present embodiment may be chosen depending on actual requirements for a device, for example, it may comprise silicon substrate, germanium (Ge) substrate, silicon-germanium (SiGe) substrate, SOI (Silicon-on-insulator) substrate or GOI (Germanium-on-Insulator) substrate, etc. As shown in FIG. 2, in a preferred embodiment of the present embodiment, the substrate 100 is silicon substrate.

Please keep referring to FIG. 2, a plurality of the fins 102 are formed on the substrate 100. In the preferred embodiment, at first, a SiN hard mask layer is formed on a surface of the substrate 100, and then a photoresist layer is coated on the mask, then performing an exposure for the photoresist layer, development and baking process to pattern the photoresist layer, and then the pattern of the photoresist layer is transferred to the hard mask, then etching the substrate 100 with the hard mask to desired depth (as the height of fins 102), and forming a plurality of fins 102 which are in long strip shape and parallel to each other on the substrate 100. The height of the fins 102 is about 10-100 nm, the top width of the fins 102 is about 5-25 nm, the length of the fin 102 is greater than 10 nm. The fins 102 comprise a first fin region 103 for forming the heterojunction bipolar transistor, and the first fin region 103 comprises a plurality of the fin 102. In the present embodiment, as shown in FIG. 2, the first fin region 103 comprises three fins 102 for example: a first fin 1021, a second fin 1022 and a third fin 1023. It is readily to be understood that the number of the fins 102 comprised by the first fin region 103 may be varied according to actual requirements, but not limited to the number shown in the present embodiment.

As shown in FIG. 3, after forming the fins 102, an isolation structure 106 is formed between the fins 102 by depositing an insulation material between the fins 102 and followed by CMP for planarization. For example, the insulation material may be silicon oxide, silicon nitride, etc. depositing between the fins 102. In the present embodiment, the isolation structure 106 is silicon oxide.

Step S102: doping the substrate, a well region of a second conductivity type being formed in the substrate to form a collector region, the well region corresponding to the first fin region.

Please keep referring to FIG. 3, after forming the isolation structure 106, ion implantation for the substrate 100 is performed. In the present embodiment, after depositing the insulation material and CMP to form the planarized isolation structure 106, ion implantation for the substrate 100 is performed with the patterned photoresist mask to form a well region 105 in the substrate 100. In the present embodiment, taking an npn heterojunction bipolar transistor for example, the well region 105 formed in the substrate 100 is N-type and serves as a collector region 105 of the heterojunction bipolar transistor. Meanwhile, the N-type well region 105 is formed in the bottom of selected fins 102 in the first fin region 103 and at least at a bottom of the fins 102. As shown in FIG. 3, the N-type well region 105 corresponds to the first fin region 103, and is formed at least at the bottom of the first fin 1021, the second fin 1022 and the third fin 1023 corresponding to the first fin region 103.

Step S103: As in FIG. 4, removing a first part of the fins in the first fin region to form a first opening.

Step S104: forming a first semiconductor layer having a first conductivity type in the first opening to form a fin base, the second conductivity type being opposite to the first conductivity type.

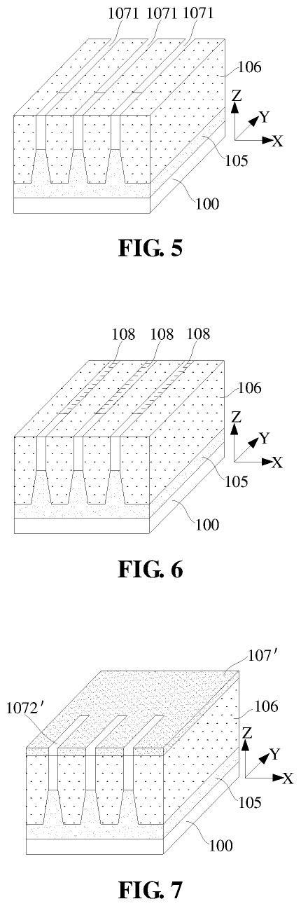

After forming the well region 105, as shown in FIG. 4, at first, a first mask 107 is formed on the substrate 100. On the first mask 107, a first window 1071′ exposing a first part of the fins 102 of the first fin region 103 is formed. The first part of the fins 102 of the first fin region 103 (such as the first fin 1021, the second fin 1022 and the third fin 1023 denoted in the present embodiment) are etched (i.e. Si etching) with the first mask 107, to form a first opening 1071 at the first part of the fins 102 of the first fin region 103 as shown in FIG. 5 (with the mask material 107 removed and upper portion of fins 1021, 1022 and 1023 etched). When etching the first part of the fins 102 of the first fin region 103, the bottom of the fin 101 connecting to the well region 105 may be kept (referring to FIG. 3). Then, as shown in FIG. 6, in the first opening 1071, a first semiconductor material is deposited to form a fin base 108. In the present embodiment, the first semiconductor material is P-type, and preferably, SiGe with Carbon atoms doped (denoted as SiGe:C). When forming the first semiconductor material layer, at first, the first opening 1071 is cleaned to remove impurities therein, and then P-type SiGe:C is selectively grown with Ge content about 10-15%, and C content about 1-5%. The whole first opening 1071 is filled with the first semiconductor material layer to form the fin base 108, and a height of the fin base 108 is about 10-100 nm.

Step S105: removing a second part of the fins of the first fin region to form a second opening.

Step S106: forming the first semiconductor material layer in the second opening, forming the fin base in the first opening and forming the first semiconductor material layer in the second opening to form a base region, the thickness of the first semiconductor material layer being smaller than the height of the second opening.

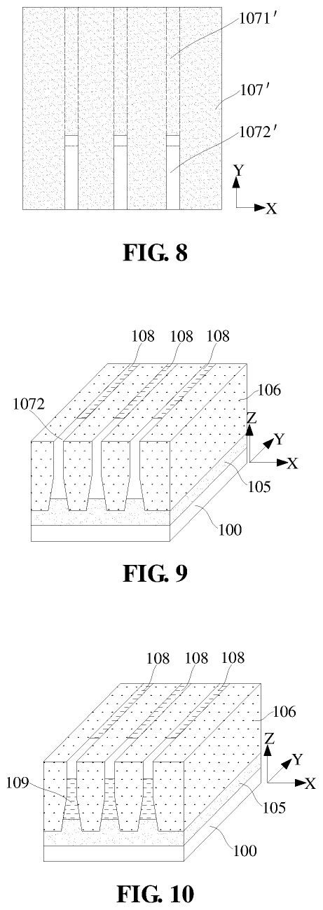

After forming the fin base 108, as shown in FIG. 7, a second mask 107′ is patterned to form the second window 1072′ on the substrate. A remaining part exposing the fins 102 of the first fin region 103 (such as the first fin 1021, the second fin 1022 and the third fin 1023 of the present embodiment) is formed on the second mask 107′, i.e. a second window 1072′ of the second part (as in FIG. 8). With the second mask 107′, the remaining part of the fins 102 of the first fin region 103 is etched (i.e. Si etching), as shown in FIG. 8, to form a second opening 1072′. When etching the remaining part of the fins 102 of the first fin region 103, similarly, a bottom 101 of the fins 102 connecting to the well region 105 is kept. In the preferred embodiment, because a base region and an emitter region are in contact to form emitter junction, the second mask 107′ and the first mask 107 may be slightly overlapped, i.e. the second window 1072′ on the second mask 107′ may be slightly overlapped with the first window 1071′ on the first mask 107. On the one hand, the etching of the fins 102 through the window 1072′ may be ensured proper remaining fins 102 (i.e. not too much etching into the bottom collector, nor too shallow than the adjacent fins with base 108) as this may affect the performance of the device; on the other hand, forming of desired continuous structure of the base region and the fin base 108 may be ensured for small base resistance for good electrical performance of the device.

Then, as shown in FIG. 9, the first semiconductor material layer is deposited again in the second opening 1072. The first semiconductor material layer partially fills within the second opening 1072, i.e. a thickness of the first semiconductor material layer is smaller than the height of the second opening, and the first semiconductor material layer filling within the second opening 1072 form a base region 109 (as in FIG. 10). As mentioned above, the first semiconductor material layer is P-type and preferably, the C doped SiGe. When forming the first semiconductor material layer, at first, the second opening 1072 is cleaned to remove impurities therein, and then P-type SiGe:C is selectively grown. A content of Ge in the P-type SiGe:C is about 10-15%, and a content of C in the P-type SiGe:C is about 1-5%. A height of the base region 109 is about 10-100 nm and shallower than the base fin 108.

Step S107: forming a second semiconductor material layer having the second conductivity type on the base region to form an emitter region.

After forming the base region 109, as shown in FIG. 10, a second semiconductor material layer is deposited (and followed by CMP for planarization) on the base region 109 to form an emitter region 110. In the present embodiment, the second semiconductor material layer is N-type polysilicon, for example, the second semiconductor material layer is As doped polysilicon. A height of the emitter region 110 is between 10-30 nm.

After forming the fin base 108, the base region 109 and the emitter region 110, a selective etching process (by photolithography patterning and dry etching) is performed to remove the isolation structure 106 on the substrate 100 to expose at least a part of the fin base 108 and the emitter region 110. As shown in FIG. 12, a base region epitaxy cap layer 111 is formed outside the fin base 108, and the base region epitaxy cap layer 111 connects to the fin base 108 altogether. Similarly, the base region epitaxy cap layer 111 is P-type SiGe, for example B doped SiGe. Then, a base (not shown) connecting to the base region 109 is formed on the base region epitaxy cap layer 111. The base region epitaxy cap layer 111 may be formed at the same time when forming a P-type source region and a drain region of a MOS device. Please keep referring to FIG. 12, an emitter region epitaxy cap layer 112 connecting to the emitter region 110 is formed outside the emitter region 110, and the emitter region the epitaxy cap layer 112 connecting to the emitter region 110 altogether. Similarly, the emitter region epitaxy cap layer 112 is N-type Si, for example, As doped polysilicon. Then, an emitter (not shown) connecting to the emitter region 110 is formed on the emitter region epitaxy cap layer 112. The emitter region epitaxy cap layer 112 may be formed at the same time when forming an N-type source region and drain region of a MOS device. Additionally, a collector electrode (not shown) connecting to the well region (the collector region) 105 in the substrate 100 is formed on the substrate.

As mentioned above, the npn heterojunction bipolar transistor is formed in the fins 102. A width of the base region 109 of the transistor may be defined with epitaxy depositing thickness of the p-type SiGe:C (i.e. the height of the base region 109) within 10 nm-100 nm. A content of Ge for moderating the band gap is within a range of 5%-20% to raise implantation efficiency of the emitter. To inhibit diffusion of boron in fin base 108 toward the emitter region 110 and the collector region 105, the doping content of C in the fin base 108 and the base region 109 is about 1%-5%.

An emitter region-base region junction area: a top width of the fins 102 (5-25 nm) and a total length of the fins 102 (>10 nm) define a total area of the emitter region-base region junction region. Because the emitter-base junction forms a vertical as well as lateral topology structure, compared with a traditional bipolar transistor, the heterojunction bipolar transistor of the present embodiment eliminates emitter edge effect of the device.

A base region-collector region junction area: a width of the bottom of the fins 102 and a total length of the fins 102 define a total area of the base-collector junction. Through doping the N well, doping level of the collector region 105 may be adjusted independently.

In the present embodiment, steps of forming a fin type field-effect transistor (Fin FET) may be further comprised, for example, at first, forming a gate oxide covering the fin 102 outside the fins 102 of a second fin region 1032, and then depositing replacement gate polysilicon and patterning the replacement gate polysilicon to form replacement polysilicon covering a channel region, and then forming a spacer layer on a sidewall of the replacement gate polysilicon. Under the function of the spacer layer, halo doping the fins 102 to form an N-type or P-type doping region. Then, epitaxy SiGe is formed at two sides of the replacement gate polysilicon, and intrinsic doping or P-type heavy doping is performed to form P-type source region and drain region. Alternately, epitaxy Si may be formed at the both sides of the replacement gate polysilicon, and intrinsic doping or N-type heavy doping may be performed to form N-type source region and drain region. When forming the N-type or P-type source region and drain region, the emitter region epitaxy cap layer 112 and the base region epitaxy cap layer 111 of the heterojunction bipolar transistor may be formed at the same time. As such, the process of making the heterojunction bipolar transistor may be integrated with the process of making a Fin FET device to simplify steps of the process and decrease cost.

Afterwards, an interlayer dielectric layer is deposited and planarized by CMP to expose the replacement gate polysilicon. Then, the replacement gate polysilicon is removed to form a gate opening, a high-K gate dielectric layer is deposited in the gate opening, work function metal layers adapted to an nMOS or pMOS device respectively is formed on the gate dielectric layer, and last, a gate metal layer is formed. Then, the source, drain and gate are formed respectively.

The present embodiment stands for an npn heterojunction bipolar transistor, and it is readily to be understood that the heterojunction bipolar transistor may be a pnp heterojunction bipolar transistor.

Above-mentioned method may be integrated into the Fin FET technology platform easily, and the formed heterojunction bipolar transistor has great electric characteristics.

### Second Embodiment

The present embodiment provides a heterojunction bipolar transistor, referring to FIG. 1 to FIG. 12, the heterojunction bipolar transistor comprises: providing a substrate 100, a plurality of fins 102 in long strip shape and parallel to each other on the substrate 100 being formed on the substrate 100, an isolation structure 106 being formed between the adjacent fins 102, the isolation structure 106 being flush with the fins 102 , the fins 102 comprising a first fin region, and the first fin region comprising a plurality of the fins 102. The substrate 100 of the present embodiment may be chosen depending on actual requirements for a device, for example, it may comprise silicon substrate, germanium (Ge) substrate, silicon-germanium (SiGe) substrate, SOI (Silicon-on-insulator) substrate or GOI (Germanium-on-Insulator) substrate, etc. As shown in FIG. 2, in a preferred embodiment of the present embodiment, the substrate 100 is silicon substrate.

The heterojunction bipolar transistor further comprises a collector region, formed in the substrate, the collector region corresponding to the first fin region; a fin base, formed in the first fin region; a base region formed in the first fin region, the base region and the fin base forming a continuous structure; and an emitter region, formed on the base region.

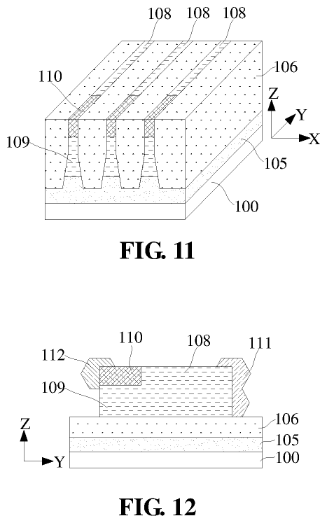

As shown in FIG. 11 and FIG. 12, in the substrate 100, a well region 105 served as a collector region is formed. In the present embodiment, the well region 105 is N-type doped well region. The well region 105 corresponds to the first fin region 103 on the substrate 100. The first fin region 103 comprises a plurality of the fins, and in the present embodiment, comprising the first fin 1021, the second fin 1022 and the third fin 1023 for example. In the present embodiment, the fin base 108 and the base region 109 may be formed by P-type SiGe, such as SiGe:C. A height of the fin base 108 is a height of the whole fins 102, which is within 10-100 nm. The height of the base region 109 is smaller than the height the fins 102 (i.e. the fin base 108), the emitter region 110 is formed on the base region 109, the height of the base region 109 is between 10-100 nm, a height of the emitter region 110 is within 10-30 nm, and a width of an emitter is within 5-25 nm. In the present embodiment, the emitter region 110 is formed by N-type polysilicon, such as As doped polysilicon.

As shown in FIG. 12, a base region epitaxy cap layer 111 is formed outside the fin base 108, the base region epitaxy cap layer 111 connects the fin base 108 altogether. The base region epitaxy cap layer 111 is P-type SiGe similarly, such as B doped SiGe. On the base region epitaxy cap layer 111, a base connecting to the fin base 108 and further connecting to the base region 109 is formed. Similarly, as shown in FIG. 12, an emitter region epitaxy cap layer 112 is formed outside the emitter region 110, and the emitter region epitaxy cap layer 112 connects the emitter region 110 altogether. The emitter region epitaxy cap layer 112 is N-type Si similarly, such as As doped polysilicon Si. On the emitter region epitaxy cap layer 112, an emitter connecting to the emitter region 110 is formed. Additionally, a collector electrode connecting to the collector region (the well region 105) is formed on the substrate 100.

As mentioned above, in the fins 102, the npn heterojunction bipolar transistor is formed. A base region 109 may be defined by epitaxy depositing thickness of the p-type SiGe:C (i.e. the height of the base region 109) with height within 10 nm-100 nm and shallower than the base region 109. A content of Ge for moderating the band gap is within a range of 5%-20% to raise implantation efficiency of the emitter. To inhibit diffusion of boron in the base region from the fin base 108 toward the emitter region 110 the collector region 105, the doping content of C in the fin base 108 and the base region 109 is about 1%-5%.

An emitter-base region junction area: a top width of the fins 102 (5-25 nm) and a total length of the fins 102 (>10 nm) define a total area of the emitter region-base region junction region. Because the emitter-base junction forms a vertical as well as lateral topology structure, compared with a traditional bipolar transistor, the heterojunction bipolar transistor of the present embodiment eliminates emitter edge effect of the junction.

A base-collector junction area: a width of the bottom of the fins 102 and a total length of the fins 102 define a total area of the base region-collector region junction. Through doping the N well, doping level of the collector region 105 may be adjusted independently.

Additionally, the heterojunction bipolar transistor may further comprise a second fin region of a MOS device on the substrate, and the MOS device may comprise an nMOS and/or pMOS device. The MOS device may comprise a channel region formed in a center region in the fins, a source region and a drain region at both sides of the channel region, a gate structure formed outside the channel region, a source and a drain outside the source region and the drain region respectively. The base region epitaxy cap layer and the emitter region epitaxy cap layer of the heterojunction bipolar transistor may be formed at the same time when forming P-type source region and drain region and N-type source region and drain region, so as to simplify the process of making the device to integrate the heterojunction bipolar transistor with the Fin FET more easily. The integrated device has great electrical performance.

The present embodiment stands for an npn heterojunction bipolar transistor, and it is readily to be understood that the heterojunction bipolar transistor may be a pnp heterojunction bipolar transistor.

As mentioned above, benefits of the heterojunction bipolar transistor and the method of making the same according to the present invention are: when making the heterojunction bipolar transistor of the present invention with applying the fin replacement technology, the fin structure may be formed on the substrate and the well region served as the collector region may be formed in the substrate, the bottom of the fin may connect to the well region served as the collector, the material of the base region may be deposited in the fins for the fin base to form the fin base, the material of the base region may be deposited in the fins for forming a heterojunction to form the base region, the fin base is connected with the base region through the epitaxy cap layer, and then various materials are deposited on the base region to be served as the emitter region. Taking an npn heterojunction transistor for example, the well region in the substrate may be N-type doped well region, and the material of the base region may be C doped P-type SiGe, the material of the emitter region may be As doped N-type polysilicon Si. The electrode contacts of the emitter, base and collector may be positioned on the surface of the device. Above-mentioned method has simple process, and may be integrated on the FinFET technology platform. The technology disclosed here carries out 14 nm and the most advanced heterojunction in the real life, based on Fin FET technology, and provides novel and improved process for integration of a 14 nm or under 14 nm SiGe HBT on the FinFET platform.

As such, for the heterojunction bipolar transistor made with above-mentioned method, its equivalent base and resistances of the collector electrode are less, leakage current of the transistor is low, electrical performance is great, and integration with a FinFET device is easier to promote integration density of the device.

It is to be understood that these embodiments are not meant as limitations of the invention but merely exemplary descriptions of the invention with regard to certain specific embodiments. Indeed, different adaptations may be apparent to those skilled in the art without departing from the scope of the annexed claims. In all instances, the scope of such claims shall be considered on their own merits in light of this disclosure, and such claims accordingly define the invention(s), and their equivalents or variations, that are protected thereby.

What is claimed is:

1. A method of making a heterojunction bipolar transistor (HBT), characterized by, comprise steps of:
providing a substrate, a plurality of fins in long strip shape and parallel to each other on the substrate being formed on the substrate, an isolation structure being formed between the adjacent fins, the isolation structure being flush with the fins, the fins comprising a first fin region, and the first fin region comprising a plurality of the fins;
doping the substrate, a well region of a second conductivity type being formed in the substrate to form a collector region, the well region corresponding to the first fin region;
removing a first part of the fins in the first fin region to form a first opening;
forming a first semiconductor material layer having a first conductivity type in the first opening to form a fin base, the second conductivity type being opposite to the first conductivity type;
removing a second part of the fins of the first fin region to form a second opening;
forming the first semiconductor material layer in the second opening, forming the fin base in the first opening and forming the first semiconductor material layer in the second opening to form a base region, the thickness of the first semiconductor material layer being smaller than the height of the second opening; and
forming a second semiconductor material layer having the second conductivity type on the base region to form an emitter region.

2. The making method according to claim 1, characterized by, wherein the step of forming a first semiconductor material layer having a first conductivity type in the first opening to form a fin base further comprises steps of:
cleaning a bottom and a sidewall of the first opening; and
selective epitaxial growing P-type SiGe in the first opening.

3. The making method according to claim 2, characterized by, wherein the steps of forming the base region and the emitter region further comprise steps of:
cleaning a bottom and a sidewall of the second opening;
selective epitaxial growing P-type SiGe in the second opening; and
forming an N-type polysilicon on the P-type SiGe.

4. The making method according to claim 2, wherein the P-type SiGe is Boron and C doped SiGe.

5. The making method according to claim 3, wherein the N-type polysilicon is As doped polysilicon.

6. The making method according to claim 1, further comprising steps of:
removing the isolation structure to expose at least a part of the fin base and a part of the emitter region;
forming a base region epitaxy cap layer outside the fin base, the epitaxy cap layer being connecting to the fin base; and
forming an emitter region epitaxy cap layer outside the emitter region, the emitter region epitaxy cap layer being connecting to the emitter region.

7. The making method according to claim 1, wherein the base region epitaxy cap layer is P-type SiGe, and the emitter region epitaxy cap layer is N-type polysilicon.

8. The making method according to claim 6, further comprising:
forming a base region electrode on the base region epitaxy cap layer;
forming an emitter electrode on the emitter region epitaxy cap layer; and
forming a collector electrode on the substrate.

9. The making method according to claim 1, wherein the fins further comprise a second fin region, and the making method further comprises steps of:
forming a replacement gate stack in a channel region of the fins of the second fin region;
forming a source region and a drain region at two ends of the channel region;
removing the replacement gate stack to a gate opening exposing the channel region; and
forming a gate structure in the gate opening.

10. The making method according to claim 1, wherein the second opening is partially formed in the fin base.

11. A heterojunction bipolar transistor, comprising:
a substrate, on which is formed with a plurality of fins being in long strip shape and parallel to each other, the fins comprising a first fin region, the first fin region comprising a plurality of the fins;
a collector region, formed in the substrate, the collector region corresponding to the first fin region;
a fin base, formed in the first fin region;
a base region formed in the first fin region, the base region and the fin base forming a continuous structure; and
an emitter region, formed on the base region.

12. The heterojunction bipolar transistor according to claim 11, wherein a material of the fin base and the base region is P-type SiGe.

13. The heterojunction bipolar transistor according to claim 11, wherein a material of the fin base and the base region is C doped SiGe.

14. The heterojunction bipolar transistor according to claim 11, wherein a material of the emitter region is N-type polysilicon.

15. The heterojunction bipolar transistor according to claim 11, wherein a material of the emitter region is As doped polysilicon.

16. The heterojunction bipolar transistor according to claim 11, further comprising:
a base region epitaxy cap layer, formed outside the fin base, the base region epitaxy cap layer being connecting to the fin base; and
an emitter region epitaxy cap layer, formed outside the emitter region, the emitter region epitaxy cap layer being connecting to the emitter region.

17. The heterojunction bipolar transistor according to claim 16, further comprising:
a base region electrode, formed on the base region epitaxy cap layer;
an emitter electrode, formed on the emitter region epitaxy cap layer; and
a collector electrode formed on the substrate.

18. The heterojunction bipolar transistor according to claim 11, wherein the fins further comprise a second fin region, the second fin region is formed with a MOS device, and the MOS device comprises:
a source region, a drain region and a channel region, the source region and the drain region being formed at two ends of the fins of the second fin region, and the channel region being positioned between the source region and the drain region; and
a gate structure, formed at edge of the channel region.
